(19) United States
(12) Patent Application Publication
(10) Pub. No.: US 2009/0051563 A1
(43) Pub. Date: Feb. 26, 2009

(54) ELECTRONIC DEVICE WITH REMOTE CONTROLLER

(75) Inventors: CHANG-YU KUO, Tu-Cheng (TW); JUNG-LIANG HUNG, Tu-Cheng (TW)

Correspondence Address: PCE INDUSTRY, INC.;ATT. CHENG-JU CHIANG, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/952,966

(22) Filed: Dec. 7, 2007

(30) Foreign Application Priority Data
Aug. 21, 2007 (CN) 200710201420.6

(51) Int. Cl. H04Q 7/00; H05K 1/18; H02J 7/00

(52) U.S. Cl. 340/825; 361/748; 320/107

(57) ABSTRACT

An electronic device includes a main housing with a plurality of electronic components contained therein, and a remote controller configured for controlling the electronic components contained in the main housing. A receptacle is formed in the main housing and a charging unit is disposed in the main housing. The remote controller is detachably docked in the receptacle and configured for being charged by the charging unit when the remote controller is installed in the receptacle.

### BACKGROUND OF THE INVENTION

1. Field of the Invention

The present invention relates generally to ubiquitous computing electronic devices, and more particularly relates to an electronic device with a detachable remote controller.

2. Description of Related Art

The convenience afforded by the use of remote controllers to control a wide range of audio-visual equipment has made remote controllers ubiquitous. The majority of audio-visual consumer electronic devices, such as television, stereo receivers, CD-ROM changers, are sold with remote controllers.

Generally, a remote controller for an electronic device is used with a dry battery installed in a main housing thereof. The dry battery needs to be replaced when the dry battery has run out. However, it is not convenient for an end user to replace the dry battery time after time. Furthermore, when the remote controller has not been used for a long time, an unexpected chemical reaction may occur in the dry battery and result in a corrosion of the main housing, even printed circuit boards contained in the main housing of the remote controller, which will adversely affect the performance of the remote controller.

Moreover, the electronic device generally has a control panel, which has same control functions as the remote controller. In other words, the electronic device is controlled by the remote controller and the control panel in parallel manner. However, the control panel adds cost to the electronic device. As consumer electronics is a highly price competitive market, device manufactures are motivated to reduce the bill of materials of a given device, enabling either higher profit or a reduced price to the end user.

Additionally, the remote controller is generally separated from the main housing of the electronic device. When the remote controller is not used, the end user usually lays the remote controller aside. Therefore, the end user tends to lose the remote controller for the carelessness. Losing the remote controller makes it inconvenient for the end user to control the electronic device.

For the foregoing reasons, there is a need for an electronic device with a remote controller which can overcome the above questions.

### SUMMARY OF THE INVENTION

An electronic device comprises a main housing with a plurality of electronic components contained therein, and a remote controller configured for controlling the electronic components contained in the main housing. A receptacle is formed in the main housing and a charging unit is disposed in the main housing. The remote controller is detachably docked in the receptacle and configured for being charged by the charging unit when the remote controller is installed in the receptacle.

Other advantages and novel features of the present invention will become more apparent from the following detailed description when taken in conjunction with the accompanying drawings, in which:

### BRIEF DESCRIPTION OF THE DRAWINGS

Many aspects of the present apparatus can be better understood with reference to the following drawings. The components in the drawings are not necessarily drawn to scale, the emphasis instead being placed upon clearly illustrating the principles of the present apparatus. Moreover, in the drawings, like reference numerals designate corresponding parts throughout the several views.

FIG. 1 is an assembled view of an electronic device with a remote controller in accordance with a first preferred embodiment of the present invention;

FIG. 2 is an exploded, isometric view of FIG. 1;

FIG. 3 is a top plan view of the remote controller of FIG. 2;

FIG. 4 is a bottom plan view of the remote controller of FIG. 2; and

FIG. 5 is an exploded view of an electronic device with a remote controller in accordance with a second preferred embodiment of the present invention.

### DETAILED DESCRIPTION OF THE INVENTION

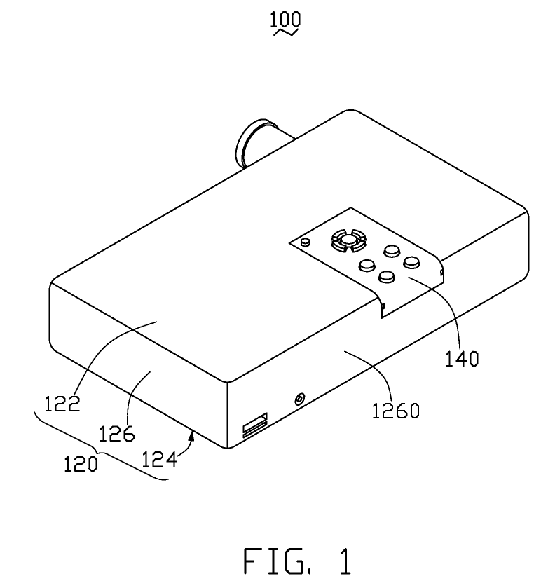

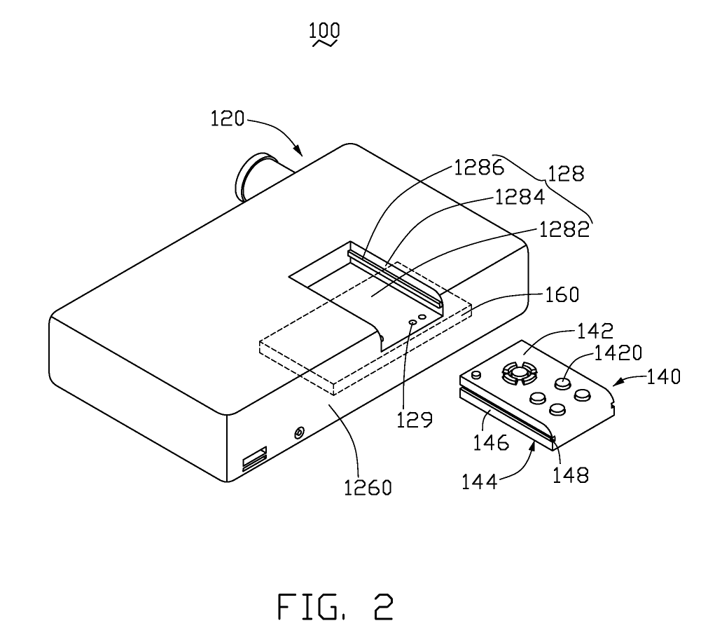

Referring to FIGS. 1-2, an electronic device 100 of a preferred embodiment of the invention comprises a main housing 120 with a plurality of electronic components contained therein and a detachable remote controller 140 configured for controlling the electronic components contained in the main housing 120. The electronic device 100 further comprises a battery charger and a receiver embedded in the main housing 120, and the receiver is for receiving controlling signals. The main housing 120 of the electronic device 100 in this embodiment is shown as a generic shape of a projection display device with rectilinear enclosure.

However, the remote controller 140 relates to a variety of electronic devices that typically include rectilinear enclosure. Examples of electronic devices for which the detachable remote controller 140 can be implemented are multiple disk CD-ROM changers, stereo receivers, VCRs, cable set-top boxes, and the like. The detachable remote controller 140 may also be utilized with other electronic devices not limited to those discussed herein. The method for attaching the detachable remote controller 140 to this main housing 120 of the electronic device 100 could easily be extended to most electronic device even through they come in a variety of shapes, sizes and designs.

The main housing 120 comprises a top case portion 122, a bottom case portion 124 and a plurality of side case portions 126 including a right side case portion 1260. A receptacle 128 is molded into the top case portion 122, and extends in a direction from the right side case portion 1260 towards a center of the top case portion 122. The receptacle 128 is shaped in such a way that the remote controller 140 can be docked in the receptacle 128.

The receptacle 128 has a slope bottom wall 1282 and three side walls 1284 extending vertically from a periphery of the bottom wall 1282. The remote controller 140 is attached to the main housing 120 by sliding into the receptacle 128 along at least one rail 1286, which is formed on the side walls 1284 and extends in a direction parallel to the extended direction of the receptacle 128. In this embodiment, there are two parallel rails 1286 formed in the receptacle 128 in such a manner that each of the two facing side walls 1284 has one rail 1286 formed thereon. Two charging pins 129 of the battery charger of the electronic device 100 are formed on a rear-right corner and electrically connected with a charging circuit (not shown) of a printed circuit board 160 (shown in dotted line) contained in the main housing 120, for charging the remote controller 140.

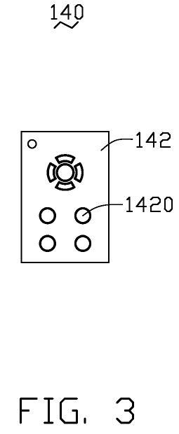

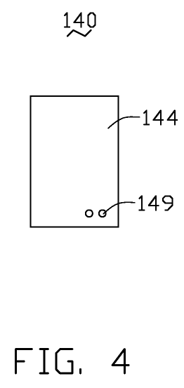

Referring also to FIGS. 3-4, the remote controller 140 is detachably installed into the receptacle 128 and has a rechargeable battery disposed therein. The remote controller 140 comprises a top cover 142 with button 1420 formed thereon, a bottom wall 144 and two sidewalls 146 extending between the top cover 142 and the bottom wall 144. A groove 148 is defined in each sidewall 146 of the remote controller 140, and extends in a direction parallel to the extended direction of the receptacle 128. The grooves 148 are corresponding to the rails 1286, respectively, so that the rails 1286 are received in the associated grooves 148 and the remote controller 140 can slide into or out of the receptacle 128 along the rails 1286. Two charging contactors 149 of the rechargeable battery are formed on the bottom wall 144 corresponding to the charging pins 129, respectively. When the remote controller 140 is retained in place within the receptacle 128, the charging contactors 149 contact with the charging pins 129, respectively. As a result, the rechargeable battery of the remote controller 140 is charged.

To make the remote controller 140 smoothly and steadily slide along the rails 1286, the bottom wall 144 of the remote controller 140 may be designed to be slanted corresponding to the bottom wall 1282 of the receptacle 128, so as to guide the remote controller 140 to move relative to the bottom wall 1282 of the receptacle 128.

As described above, the receptacle 128 is designed with a profile corresponding to the remote controller 140 and works in such a way that the remote controller 140 can slide into place but can not be maneuvered perpendicularly to the direction that it slides due to an engagement of the rails 1286 and the grooves 148. In other words, the remote controller 140 is slidably engaged in the receptacle 128 in a first direction and is fixed in position in a second direction perpendicular to the first direction. In this way, an end user can easily attach or detach the remote controller 140, but in the absence of an external force other than gravity the remote controller 140 will remain in place within the receptacle 128 of the main housing 120.

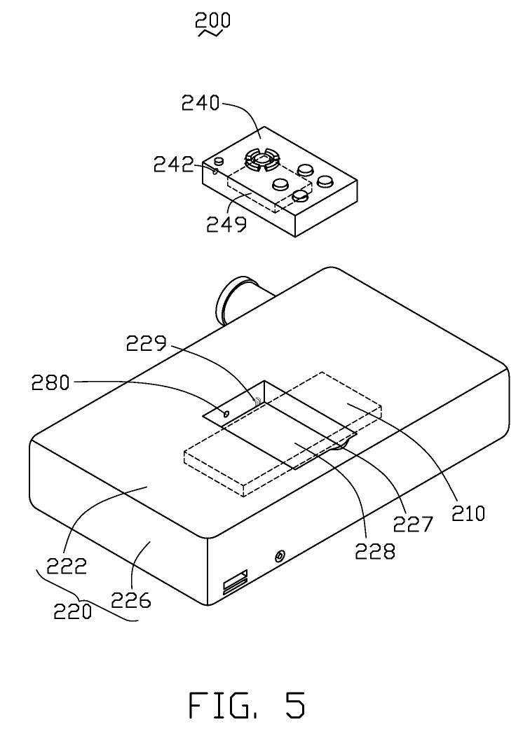

FIG. 5 illustrates an electronic device 200 of a second preferred embodiment of the invention. The main difference between the electronic device 200 and the electronic device 100 is that a receptacle 228 formed on a top case portion 222 of a main housing 220 of the electronic device 200 is away from side case portions 226 thereof. A cutout 227 is formed on the top case portion 222 adjacent to the receptacle 228, and serves to facilitate pulling the remote controller 240 out of the receptacle 228. Two charging pins 229 are formed on a left sidewall of the receptacle 228 and face the cutout 227. When the remote controller 240 is installed into the receptacle 228 along a direction perpendicular to the top case portion 222, two charging contactors (not shown) of the remote controller 240 contact the corresponding charging pins 229 to charging the remote controller 240.

Furthermore, the remote controller 240 can be charged in other manners such as electromagnetic interaction. For example, an electromagnetic wave generator 210 is positioned in the main housing 220 to produce electromagnetic waves at a given frequency when the electronic device 200 is used. Meanwhile, an electromagnetic wave receiver 249 is disposed in the remote controller 240 to receive and convert the electromagnetic waves into electric current to charge the remote controller 240.

As mentioned above, the remote controller 140, 240 can be charged in manner of direct contact charge mode which is via engagement of the charging pins 129, 229 and the charging contactors 149, and non-contact charge mode which is via the electromagnetic interaction, taken alone or in combination. Therefore, the remote controller 140, 240 need not to apply dry batteries, and the corrosion caused by the dry batteries in the electron device in related art is avoided.

Furthermore, the remote controller 140, 240 is detachably attached to the main housing 120, 220, the remote controller 140, 240 can be attached to the main housing 120, 220 when the remote controller 140, 240 is not used. Therefore, the remote controller 140, 240 is not easily to be lost. Additionally, the control panel of the electron device in related art, which has same control functions as the remote controller 140, 240, can be omitted to reduce the cost of the electronic device 100, 200.

Additionally, as shown in FIG. 5, the remote controller 240 further comprises a transmitter 242 for transmitting controlling signals. The electronic device 200 further comprises a receiver 280 for receiving the controlling signals. The receiver 280 is exposed outside the main housing 220 and in the receptacle 228. The remote controller 240 is detachably mounted in the receptacle 228 in a manner that the transmitter 242 of the remote controller 240 aligns with the receiver 280 so as to control the electronic device 200.

It is believed that the present invention and its advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. An electronic device comprising:
a main housing with a plurality of electronic components contained therein, a receptacle being formed in the main housing, a charging unit being disposed in the main housing; and
a remote controller configured for controlling the electronic components contained in the main housing;
wherein the remote controller is detachably docked in the receptacle and configured for being charged by the charging unit when the remote controller is installed in the receptacle.

2. The electronic device as described in claim 1, further comprising a printed circuit board with a charging circuit contained in the main housing, wherein the charging unit comprises charging pins disposed in the receptacle and electrically connected with the charging circuit of the printed circuit board contained in the main housing, and the remote controller has charging contactors formed thereon, the remote controller being charged via an engagement of the charging pins and the charging contactors.

3. The electronic device as described in claim 2, wherein the charging unit further comprises an electromagnetic wave generator disposed in the main housing to produce electromagnetic waves when the electronic device is used, and the remote controller has an electromagnetic wave receiver disposed therein to receive and convert the electromagnetic waves into electric current to charge the remote controller.

4. The electronic device as described in claim 1, wherein the charging unit comprises an electromagnetic wave generator disposed in the main housing to produce electromagnetic waves when the electronic device is used, and the remote controller has an electromagnetic wave receiver disposed therein to receive and convert the electromagnetic waves into electric current to charge the remote controller.

5. The electronic device as described in claim 1, wherein the main housing houses a projection display device therein.

6. The electronic device as described in claim 1, wherein the remote controller is slidably engaged in the receptacle in a first direction and is fixed in position in the second direction perpendicular to the first direction.

7. The electronic device as described in claim 1, wherein the receptacle is sunken inwardly from the main housing.

8. The electronic device as described in claim 7, wherein the main housing has a rail formed in the receptacle, and the remote controller has a groove defined therein, wherein the rail is for being received in the groove and the remote controller slides into or out of the receptacle along the rail.

9. The electronic device as described in claim 8, wherein the main housing comprises a top case portion, a bottom case portion and a plurality of side case portions, and the receptacle is defined in the top case portion and extends in a direction from one of the side case portion towards a center of the top case portion; wherein the rail extends in a direction from the one of the side case portion towards a center of the top case portion.

10. The electronic device as described in claim 9, wherein the receptacle has a bottom wall and three side walls extending from a periphery of the bottom wall, and the rail is formed on one of the bottom wall and the three side walls.

11. The electronic device as described in claim 9, wherein the receptacle has a bottom wall and three side walls extending from a periphery of the bottom wall, and the rail is formed on one of the three side walls; the main housing further comprises another rail formed on one of the three side walls facing the rail; wherein the remote controller has an another groove defined therein, wherein the another rail is received in the another groove and the remote controller slides into or out of the receptacle along the rail and the another rail.

12. The electronic device as described in claim 11, wherein the rail is parallel to the another rail.

13. The electronic device as described in claim 11, wherein the bottom wall of the receptacle is slanted relative to the bottom case portion, and the remote controller has a slope bottom wall corresponding to the bottom wall of the receptacle so as to guide the remote controller to move relative to the bottom wall of the receptacle.

14. The electronic device as described in claim 7, wherein the main housing comprises a top case portion, a bottom case portion and a plurality of side case portions, and the receptacle is defined in the top case portion away from the side case portions.

15. The electronic device as described in claim 14, wherein the main housing comprises a cutout defined in the top case portion near the receptacle for facilitate pulling the remote controller out of the receptacle.

16. An electronic device comprising:
a main housing with a plurality of electronic components contained therein, a receptacle being formed in the main housing, a rail being formed on the main housing in the receptacle; and
a remote controller configured for controlling the electronic components contained in the main housing, a groove being defined in the remote controller corresponding to the rail;
wherein the rail is configured for being inserted in the groove and the remote controller is slidable into or out of the receptacle along the rail.

17. An electronic device assembly comprising:
an electronic device having a housing, a battery charger embedded in the housing, and a remote controller receptacle formed on the housing, the battery charger having a plurality of electrical contacts exposed outside the housing in the receptacle; and
a remote controller for controlling the electronic device, the remote controller having a rechargeable battery, the remote controller being configured for detachably mounting in the remote controller receptacle of the electronic device in a manner that the rechargeable battery is electrically coupled to the electrical contacts of the battery charger.

18. The electronic device as described in claim 17, wherein the remote controller includes a transmitter for transmitting controlling signals, the electronic device includes a receiver for receiving the controlling signals, the remote controller being detachably mounted in the remote controller receptacle of the electronic device in a manner that the transmitter of the remote controller aligns with the receiver of the electronic device.

19. The electronic device as described in claim 18, wherein the receiver of the electronic device is exposed outside the housing and in the remote controller receptacle of the electronic device.
